(19) United States
(12) Patent Application Publication
(10) Pub. No.: US 2025/0369107 A1
(43) Pub. Date: Dec. 4, 2025

(54) CONTAINER ASSEMBLIES, CHAMBER ARRANGEMENTS AND SEMICONDUCTOR PROCESSING SYSTEMS INCLUDING CONTAINER ASSEMBLIES, AND METHODS OF MAKING CONTAINER ASSEMBLIES AND DEPOSITING MATERIAL LAYERS

(71) Applicant: ASM IP Holding B.V., Almere (NL)

(72) Inventors: Aniket Chitale, Phoenix, AZ (US); Fan Gao, Chandler, AZ (US); Wentao Wang, Chandler, AZ (US); Junwei Su, Chandler, AZ (US); Mingyang Ma, Phoenix, AZ (US); Jingcheng Zhou, Tempe, AZ (US); Taison Ku, Tempe, AZ (US); Steven Harris, Westminster, CO (US)

(21) Appl. No.: 19/222,103

(22) Filed: May 29, 2025

Related U.S. Application Data
(60) Provisional application No. 63/654,595, filed on May 31, 2024.

(51) Int. Cl. C23C 16/452; C23C 16/455

(52) U.S. Cl. CPC C23C 16/452; C23C 16/45561

(57) ABSTRACT

A container assembly is provided. The container assembly includes a vessel, a conduit and a jacket. The vessel is formed from a first material having a first thermal conductivity, the conduit is seated in the vessel and is in communication with an interior of the vessel, and the jacket extends about the vessel and is formed from a second material having a second thermal conductivity. The second thermal conductivity is greater than the first thermal conductivity and the jacket is affixed to the vessel with an interference fit to limit resistance to heat flow between the vessel and the jacket. Chamber arrangements and semiconductor processing systems, material layer deposition methods and methods of making container assemblies are provided.

### CROSS-REFERENCE TO RELATED APPLICATIONS

This application claims priority to and the benefits of U.S. Provisional Patent Application No. 63/654,595, filed on May 31, 2024, the contents of which are incorporated herein by reference in their entirety.

### FIELD OF INVENTION

The present disclosure generally relates to fluid systems, and more particularly to fluid systems employed to communicate vaporized liquid fluids.

### BACKGROUND OF THE DISCLOSURE

Fluid systems are commonly employed to communicate fluids from fluid sources to fluid destinations. In some fluid systems the process fluid may be contained within the fluid source in a liquid state and liquid fluid vaporized prior to communication to the fluid destination, such as in liquid material layer precursors employed in gas-phase reactors to deposit material layers onto substrates. Vaporization of the liquid process fluid may be accomplished by introducing a gas into the liquid process contained within the fluid source to charge a headspace within the fluid source with vaporized liquid process fluid and drawing off the vaporized process fluid for communication to the process fluid destination. Concentration of the vaporized process fluid within the headspace is typically controlled by driving temperature of the liquid process fluid and vaporized process fluid, and pressure within the headspace occupied by the vaporized liquid process fluid, to a desired temperature and pressure.

Such systems and methods have generally been considered suitable for their intended purpose. However, there remains a need in the art for improved container assemblies, chamber arrangements and semiconductor processing systems including container assemblies, and related material layer deposition methods and methods of making container assemblies. The present disclosure provides a solution to this need.

### SUMMARY OF THE DISCLOSURE

A container assembly is provided. The container assembly includes a vessel, a conduit and a jacket. The vessel is formed from a first material having a first thermal conductivity, the conduit is seated in the vessel and is in communication with an interior of the vessel, and the jacket extends about the vessel and is formed from a second material having a second thermal conductivity. The second thermal conductivity is greater than the first thermal conductivity and the jacket is affixed to the vessel with an interference fit to limit resistance to heat flow between the vessel and the jacket.

In addition to one or more of the features described above, or as an alternative, further examples of the container assembly may include that the conduit is first conduit and the container assembly further includes a second conduit and a third conduit. The second conduit may be seated in the vessel, may be in fluid communication with the interior of the vessel, and may extend into the interior of the vessel by a distance greater than that of the first conduit. The third conduit may be seated in the vessel, may be in fluid communication with the interior of the vessel, and may extend into the interior of the vessel to a location beyond that of the second conduit.

In addition to one or more of the features described above, or as an alternative, further examples of the container assembly may include that the first conduit includes a first manual valve and a first actuated valve arranged therealong, that the second conduit includes a second manual valve and a second actuated valve arranged therealong, and that the third conduit includes a third manual valve and a third actuated valve arranged therealong.

In addition to one or more of the features described above, or as an alternative, further examples of the container assembly may include a probe member. The probe member may be seated in the vessel. The probe member may extend into the interior of the vessel. The probe member may include a temperature sensor configured to acquire temperature within the vessel. The probe member may include one more level sensor configured to acquire a level of a liquid contained within the vessel.

In addition to one or more of the features described above, or as an alternative, further examples of the container assembly may include that the vessel is formed from a stainless steel material and that the jacket is formed from an aluminum-containing material.

In addition to one or more of the features described above, or as an alternative, further examples of the container assembly may include that an interference between the vessel and the jacket is between about 0.005 millimeters and about 0.345 millimeters, or between about 0.112 millimeters and about 0.178 millimeters, or between about 0.163 millimeters and about 0.229 millimeters, or between about 0.241 and about 0.345 millimeters.

In addition to one or more of the features described above, or as an alternative, further examples of the container assembly may include a thermoelectric heat pump, a heat sink, and a coolant circuit. The thermoelectric heat pump may be coupled to the jacket. The heat sink may be coupled to the thermoelectric heat pump. The coolant circuit may be connected to the heat sink and configured to circulate a liquid coolant across the heat sink.

In addition to one or more of the features described above, or as an alternative, further examples of the container assembly may include that the vessel has a vessel wall thickness, that the jacket has a jacket wall thickness, and that the jacket wall thickness is greater than the vessel wall thickness.

In addition to one or more of the features described above, or as an alternative, further examples of the container assembly may include that the thermoelectric heat pump is a first thermoelectric heat pump, that the container assembly further includes comprises one or more second thermoelectric heat pump coupled to the jacket, and that the heat sink is coupled to the one or more second thermoelectric heat pump.

In addition to one or more of the features described above, or as an alternative, further examples of the container assembly may include that the second thermoelectric heat pump is connected to a probe member seated in the vessel and thermally coupled therethrough to an interior of the container assembly.

In addition to one or more of the features described above, or as an alternative, further examples of the container assembly may include that the jacket has one or more protruding portion extending in a direction opposite the conduit. The thermoelectric heat pump may be coupled to the one or more protruding portion of the jacket.

In addition to one or more of the features described above, or as an alternative, further examples of the container assembly may include that the one or more protruding portion is a first protruding portion and that the jacket has second protruding portion spaced apart from the first protruding portion. The thermoelectric heat pump may be a first thermoelectric heat pump seated on the first protruding portion and a second thermoelectric heat pump may be seated on the second protruding portion of the jacket.

In addition to one or more of the features described above, or as an alternative, further examples of the container assembly may include a thermal insulator extending about the jacket and separated from the vessel by the jacket.

In addition to one or more of the features described above, or as an alternative, further examples of the container assembly may include a liquid precursor contained within the interior of the vessel. The liquid precursor may be selected from the group consisting of a silicon-containing precursor, germanium-containing precursor, a phosphorous-containing precursor, and an arsenic-containing precursor.

A chamber arrangement is provided. The chamber arrangement includes a chamber body having a horizontal crossflow arrangement and a container assembly as described above. The first material forming the vessel is a stainless steel material, the second material forming the jacket is an aluminum-containing material, and the conduit couples the vessel to the chamber body to deposit a material layer onto a substrate seated within the chamber body using vaporized liquid precursor communicated from with the interior of the vessel.

A semiconductor processing system is provided. The semiconductor processing system includes a container assembly as described above, a chamber arrangement, and a controller. The vessel included in the container assembly is formed from a stainless steel material, the jacket included in the container assembly is formed from an aluminum-containing material, and a thermoelectric heat pump coupled to the jacket. The chamber arrangement is coupled to the conduit and is configured to deposit a material layer onto a substrate using a vaporized liquid material layer precursor received from the container assembly. The controller is operatively connected to the thermoelectric heat pump and responsive to instructions recorded on a memory to receive a temperature measurement of temperature of a liquid precursor contained within the interior of the vessel, receive a predetermined liquid precursor temperature value, compare the temperature measurement to a predetermined temperature value, and throttle rate of heat transfer between the liquid precursor and the heat sink using the thermoelectric heat pump when the temperature measurement received by the controller differs from the predetermined temperature measurement by more than a predetermined differential.

A material layer deposition method is provided. The method includes, at a container assembly as described above, receiving a carrier gas at the vessel, vaporizing a liquid precursor contained within an interior of the vessel, communicating the vaporized liquid precursor to a chamber arrangement coupled to the conduit using the carrier gas, and depositing a material layer onto a substrate seated within the chamber arrangement using the vaporized liquid precursor. It is contemplated that vaporizing the liquid precursor include transferring heat between the liquid precursor and an external environment outside of the container assembly through the vessel and the jacket. It is also contemplated that the interference fit between the vessel and the jacket limit resistance to heat transfer between vessel and the jacket during transfer of the heat between the liquid precursor and the external environment.

A method of making a container assembly is provided. The method includes forming a vessel from a first material having a first thermal conductivity, seating a conduit in the vessel such that the conduit is in communication with an interior of the vessel, and forming a jacket from a second material having a second thermal conductivity that is greater than the first thermal conductivity of the first material forming the jacket. The vessel is arranged (e.g., inserted so as to be positioned) in the jacket such that the jacket extends about the vessel and the jacket affixed to the vessel with an interference fit such that the interference fit between the jacket and the vessel limits resistance to heat flow between the jacket and the vessel during transfer of the heat between the liquid precursor and the external environment.

In addition to one or more of the features described above, or as an alternative, further examples of the method may include that affixing the jacket to the vessel with the interference fit includes cooling the vessel prior to arranging the jacket about the vessel and heating the vessel subsequent to arranging jacket about vessel such that the heating of the vessel forms the interference fit between the jacket and the vessel.

In addition to one or more of the features described above, or as an alternative, further examples of the method may include that affixing the jacket to the vessel with the interference fit includes heating the jacket prior to arranging the jacket about the vessel and cooling the jacket subsequent to arranging the jacket about vessel such that the cooling of the vessel forms the interference fit between the jacket and the vessel.

In addition to one or more of the features described above, or as an alternative, further examples of the method may include that affixing the jacket to the vessel with the interference fit comprises press fitting the vessel in the jacket.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic diagram of a semiconductor processing system with a container assembly in accordance with the present disclosure, showing the container assembly communicating a flow of a vaporized liquid precursor to a chamber arrangement;

FIG. 2 is a cross-section side view of the chamber arrangement of FIG. 1 according to an example of the present disclosure, schematically showing a material layer being deposited onto a substrate seated within the chamber arrangement using the vaporized liquid precursor;

FIG. 3 is a cross-sectional side view of the container assembly of FIG. 1 according to an example of the present disclosure, schematically showing a vessel containing a liquid precursor with a jacket extending about the exterior of the vessel and coupled to one or more thermoelectric heat pumps, a heat sink, and a heat transfer circuit;

FIG. 4 is a cross-sectional side view of the container assembly of FIG. 1 according to an example of the present disclosure, schematically showing a vessel containing a liquid precursor with a jacket interference fit to an exterior of the vessel;

FIG. 5 is a plan view of a portion of the container assembly shown in FIG. 1 according to an example of the present disclosure, schematically showing apertures defined in a top portion of the vessel for seating accessories in the vessel;

FIG. 6 is an exploded view of the container assembly of FIG. 1 according to an example of the present disclosure, schematically showing the jacket and accessories exploded away from the vessel;

FIG. 7 is a block diagram of a controller included in the semiconductor processing system of FIG. 1 according to an example of the present disclosure, schematically showing inputs to and output from the controller during vaporization of a liquid precursor contained within the interior of the vessel;

FIG. 8 is a block diagram of a method of depositing a material layer onto a substrate using vaporized liquid precursor received from the container assembly according to an example of the present disclosure, showing operations of the method according to an illustrative and non-limiting example of the method;

FIG. 9 is a block diagram showing operations for controlling temperature of the liquid precursor contained within the container assembly, showing the operations according to an illustrative and non-limiting example of the method of FIG. 8; and

FIG. 10 is a block diagram of a method of making a container assembly in accordance with the present disclosure, showing operations of the method according an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

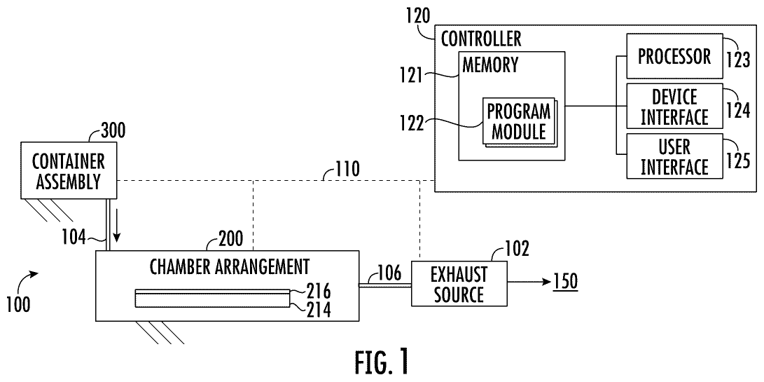

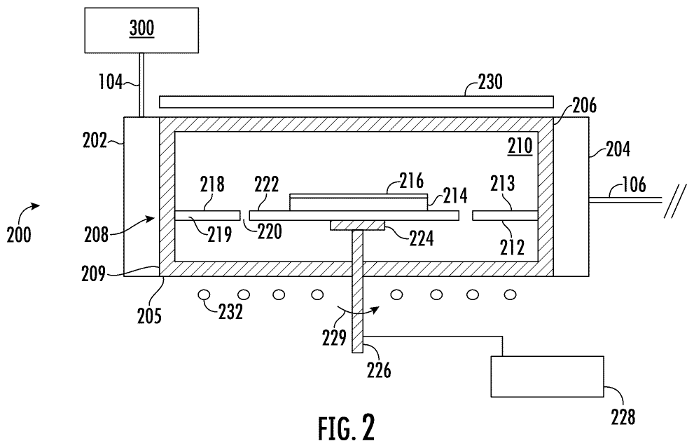

Reference will now be made to the drawings wherein like reference numerals identify similar structural features or aspects of the subject disclosure. For purposes of explanation and illustration, and not limitation, an example of a semiconductor processing system including a container assembly in accordance with the present disclosure is shown in FIG. 1, and is designated generally by reference character 100. Other examples of container assemblies, chamber arrangements and semiconductor processing systems including container assemblies, and related material layer deposition methods and methods of making container assemblies, as will be described, are provided in FIGS. 2-10. The systems and methods of the present disclosure may be used to vaporize liquids, such as liquid material layer precursors employed to deposit silicon-containing material layers onto substrates using epitaxial techniques, though the present disclosure is not limited to an particular type of material layer deposition technique nor to material layer deposition in general.

Referring to FIG. 1, the semiconductor processing system 100 is shown. The semiconductor processing system 100 generally includes a container assembly 300, a chamber arrangement 200, an exhaust source 102, and a controller 120. The container assembly 300 is fluidly connected to the chamber arrangement 200 via a precursor supply conduit 104 and is configured to communicate a vaporized liquid precursor 304 to the chamber arrangement 200. The chamber arrangement 200 is configured to expose a substrate 214 seated within the chamber arrangement 200 to the vaporized liquid precursor 304 under conditions selected to cause a material layer 216 to deposit onto the substrate 214 using the vaporized liquid precursor 304. The exhaust source 102 fluidly couples the chamber arrangement 200 via an exhaust conduit 106 to the external environment 150 outside of the semiconductor processing system 100, for example through a vacuum pump and/or an abatement device such as a scrubber, to communicate residual vaporized liquid precursor and/or reaction by-products issued by the chamber arrangement 200 to the external environment 150 outside of the semiconductor processing system 100.

In accordance with certain examples of the disclosure, the container assembly 300 may be positioned proximate to the chamber arrangement 200 for providing vaporized liquid precursor to the chamber arrangement 200. As will be described, the container assembly 300 is configured to maintain the temperature of a liquid precursor that is contained within the container assembly 300 within a predetermined range (e.g., within a predetermined temperature differential), to ensure safe operation of the semiconductor processing system 100 and/or reliable delivery of the vaporized liquid precursor. In this regard, the container assembly 300 may be positioned within 10 feet of the chamber arrangement 200, or within 5 feet of the chamber arrangement 200, or within 3 feet of the chamber arrangement 200. For example, the container assembly 300 may be supported above or below the chamber arrangement 200 to limit (e.g., minimize) the footprint of the semiconductor processing system 100. In certain embodiments, the chamber arrangement includes the container assembly 300. Positioning the container assembly 300 proximate to the chamber arrangement 200, reduces the risk of the vaporized liquid precursor condensing in the precursor supply conduit 104 connecting the container assembly 300 to the chamber arrangement 200 and may simplify the design of the semiconductor processing system 100.

As used herein, a “liquid precursor” generally refers to a compound that participates in a chemical reaction to form another compound or element. A portion of the liquid precursor (an element or group within the precursor) may be incorporated into the compound or element that results from the chemical reaction. For example, the compound or element that results from the chemical reaction may be a layer and/or a film that is formed on a surface of a substrate. In other instances, the compound or element that results from the chemical reaction does not contain a portion, or a significant portion, of the liquid precursor (an element or group within the precursor). In this regard, liquid etchants, passivation agents, reducing agents and the like are included within the scope of the liquid precursor. Generally, the liquid precursor is a liquid in at least over a temperature range of about 5° C. to room temperature (e.g., about 20-23° C.) at standard pressure.

In certain examples, the liquid precursor may comprise, consist of, or consist essentially of a silicon-containing liquid precursor. In this respect, the silicon-containing liquid precursor includes at least one silicon atom and one or more additional elements such as, for example, one or more of carbon, nitrogen, oxygen, halogen (e.g., F, Cl, Br, and I), phosphorous, and hydrogen. Examples of suitable silicon-containing liquid precursors include, but are not limited, to a silane (e.g., silane (SiH₄), disilane (Si₂H₆), trisilane (Si₃H₈), and tetrasilane (Si₄H₁₀)), a halosilane (e.g., chlorosilane (SiH₃Cl), dichlorosilane (SiH₂Cl₂), trichlorosilane (SiHCl₃), tetrachlorosilane (SiCl₄), bromosilane (SiH₃Br), iodosilane (SiH₃I), diiodosilane (SiH₂I₂) hexachlorodisilane (HCDS, Si₂Cl₆), and octachlorotrisilane (OCTS, Si₃Cl₈)), an organosilane (e.g., methylsilane (SiH₃CH₃), dimethylsilane (SiH₂(CH₃)₂), trimethylsilane (SiH(CH₃)₃), and tetramethylsilane (Si(CH₃)₄)), an aminosilane, an oxysilane, and a silylphosphide (e.g., trisilylphosphine (P(SiH₃)₃)). In other examples, the liquid precursor may comprise, consist of, or consist essentially of a germanium-containing liquid precursor. In this respect, the germanium-containing liquid precursor includes at least one germanium atom and one or more additional elements such as, for example, one or more of carbon, nitrogen, oxygen, halogen (e.g., F, Cl, Br, and I), and hydrogen. Examples of suitable germanium-containing liquid precursors include, but are not limited, to a germane (e.g., germane (GeH₄), digermane (Ge₂H₄), and trigermane (Ge₃H₈)), a halogermane (e.g., dichlorogermane (GeH₂Cl₂), trichlorogermane (GeHCl₃), tetrachlorogermane (GeCl₄), tetrabromogermane (GeBr₄)), a germylsilane (e.g., silylgermane (GeH₃SiH₃)), an organogermane, an aminogermane, and an oxygermane. In yet other examples, the liquid precursor may comprise, consist of, or consist essentially of a dopant-containing precursor such as a p-type dopant (e.g., boron (B), aluminum (Al), gallium (Ga), and indium (In)) or an n-type dopant (e.g., phosphorous (P), arsenic (As), antimony (Sb), bismuth (Bi), and lithium (Li)). Examples of n-type dopant containing precursors include arsenic-containing liquid precursors, such as, for examples, tertbutylarsine (C₄H₁₁As).

The chamber arrangement 200 includes a means for seating a substrate 214 within a chamber body where deposition conditions can be controlled. A variety of different chamber arrangement configurations are possible. For example, the chamber arrangement may have a flow-type configuration, such as a cross-flow configuration. In another example, the chamber arrangement may have a showerhead type configuration. In yet another example, the chamber arrangement may have a space-divided reactor type configuration. In some embodiments, the chamber arrangement is a batch reactor for processing multiple substrates simultaneously. In other embodiments, the chamber arrangement is a single wafer deposition reactor. In certain embodiments, the chamber arrangement 200 has a single-wafer cross-flow configuration (e.g., shown in FIG. 2).

As used herein the term “substrate” refers to an underlying material or materials that may be used to form, or upon which, a device, a circuit, a material, or a material layer may be formed. A substrate may be continuous or non-continuous; rigid or flexible; solid or porous; and combinations thereof. A substrate may be in any form, such as, for example, a powder, a sheet, a plate, or a workpiece. Substrates in the form a sheet and may extend beyond the bounds of a chamber body where a deposition process occurs and, in some cases, move through the chamber body such that the process continues until the end of the substrate is reached. Substrates in the form of a plate may include wafers in various shapes and sizes, for example, including 200- and 300-millimeter wafers. A substrate may be made from semiconductor materials, including, for example, silicon, silicon germanium, silicon oxide, gallium arsenide, gallium nitride, and silicon carbide. A substrate can include one or more layers overlying a bulk material, for example the substrate may include nitrides, oxides, insulating materials, dielectric materials, conductive materials, metals, crystalline materials, epitaxial, heteroepitaxial, and/or single crystal materials. A substrate can include various topologies, such as, for example, gaps, recesses, lines, trenches, vias, holes, or spaces between elevated portions, such as fins, and the like formed within or on at least a portion of a layer of the substrate.

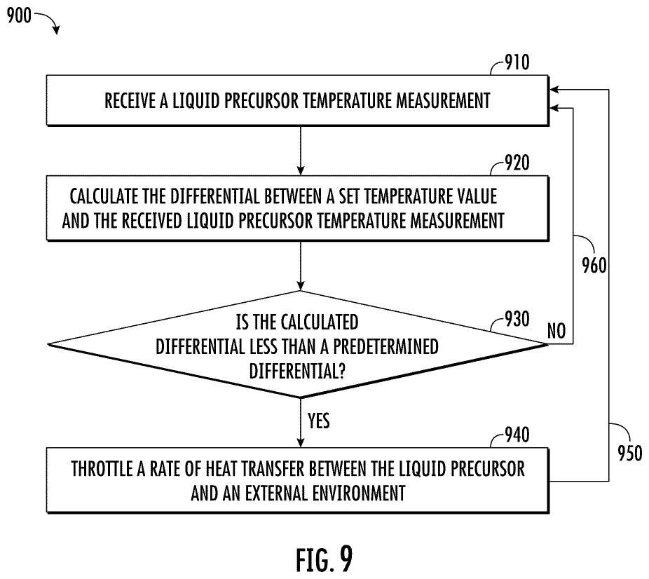

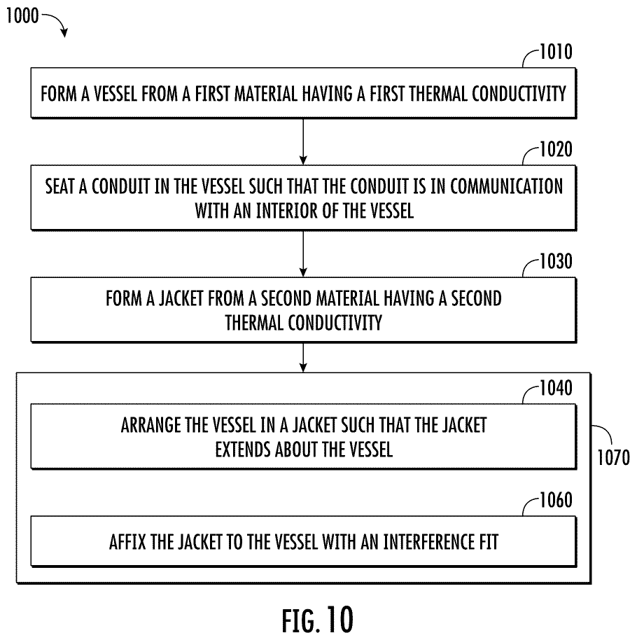

The controller 120 may be operably connected to one or more of the container assembly 300, the chamber arrangement 200, and the exhaust source 102, for example to control the flow of the vaporized liquid precursor from the container assembly 300 into the chamber arrangement 200 and/or to control processing of the substrate 214 within the chamber arrangement 200. The controller 120 generally includes a device interface 124, a processor 123, a user interface 125, and a memory 121. The device interface 124 connects the processor 123 via a wired or wireless link 110 to the container assembly 300, the chamber arrangement 200, and/or the exhaust source 102. The processor 123 is in turn operably connected to the user interface 125, for example, to receive a user input and/or provide a user output and is in communication with the memory 121. The memory 121 may include a non-transitory machine-readable medium having a plurality of program modules 122 recorded thereon that, when read by the processor 123, cause the processor 123 to execute certain operations. Among the operations are operations of a material layer deposition method (e.g., shown in FIGS. 9 and 10) using a vaporized liquid precursor, as will be described. Although shown and described herein as having a specific architecture, it is to be understood and appreciated that other controller architectures may be employed, e.g., distributed architectures, and remain within the scope of the present disclosure.

With reference to FIG. 2, a chamber arrangement 200 that has a single-wafer cross-flow configuration is shown according to some embodiments of the present disclosure. The chamber arrangement 200 includes an injection flange 202, a chamber body 208, and an exhaust flange 204. In the illustrated example, a precursor supply conduit 104 provides vaporized liquid precursor from the container assembly 300 through the injection flange 202 into the chamber body 208 that has a substrate 214 seated therein to deposit a material layer 216 on the surface of the substrate 214. Residual vaporized liquid precursor and other process gasses and reaction by-products are removed through the exhaust flange 204 and exhaust conduit 106. The chamber arrangement further includes an upper heater element array 230, a lower heater element array 232, a divider 218, and a lift and rotate module 228. Although shown and described herein as including certain elements and a having a specific arrangement, it is to be understood and appreciated that the chamber arrangement 200 may include other elements and/or exclude certain elements described herein, or have another arrangement, and remain within the scope of the present disclosure.

The chamber body 208 has an injection end 205 and a longitudinally opposite exhaust end 206 and is formed from a transparent material 209 (e.g., a material transmissive to electromagnetic radiation within an infrared waveband) and may include a plurality of external ribs extending laterally about an exterior of the chamber body 208 and longitudinally spaced apart from one another between the injection end 205 and the exhaust end 206 of the chamber body 208. The injection flange 202 is connected to the injection end 205 of the chamber body 208 and fluidly couples the precursor supply conduit 104 to an interior 210 of the chamber body 208. The exhaust flange 204 is connected to the exhaust end 206 of the chamber body 208 and fluidly couples the interior 210 of the chamber body 208 to the exhaust source 102.

The upper heater element array 230 and the lower heater element array 232 are supported above and below the chamber body 208, respectively, each including a plurality of heater elements configured to heat a substrate 214 when seated within the interior 210 of the chamber body 208. In this respect, the plurality of heater elements of the upper heater element array 230 and the lower heater element array 232 may be configured to emit electromagnetic radiation within an infrared waveband that passes through the transparent material 209 into the interior 210 of the chamber body 208. In certain examples, the upper heater element array 230 and the lower heater element array 232 may include linear filament heat lamps. In accordance with certain examples, the upper heater element array 230 and/or the lower heater element array 232 may include spot lamps.

The divider 218 is fixed within the chamber body 208 and divides the interior 210 of the chamber body 208 into an upper portion 213 and a lower portion 212. The divider 218 may be formed from an opaque material 219 (e.g., a material opaque to electromagnetic radiation within an infrared waveband). In certain examples, the opaque material 219 may include a bulk silicon carbide material. In accordance with certain examples, the opaque material 219 may include a bulk carbonaceous material with a silicon carbide material, such as bulk graphite or pyrolytic carbon by way of non-limiting example. The divider 218 defines an aperture 220 that fluidly couples the upper portion 213 of the chamber body 208 to the lower portion 212 of the chamber body 208. A substrate support 222 may be arranged within aperture 220 to support the substrate 214 during deposition of the material layer 216 onto the substrate 214, (e.g., according to the operations shown in FIGS. 9 and 10). It is also contemplated that, in accordance with certain examples, the substrate support 222 may be connected to a lift and rotate module 228 via a support member 224 and a shaft member 226 that may be configured rotate the support member about a rotation axis 229 within the aperture 220. In accordance with certain examples, a support member 224 and a shaft member 226 may be formed from the transparent material 209.

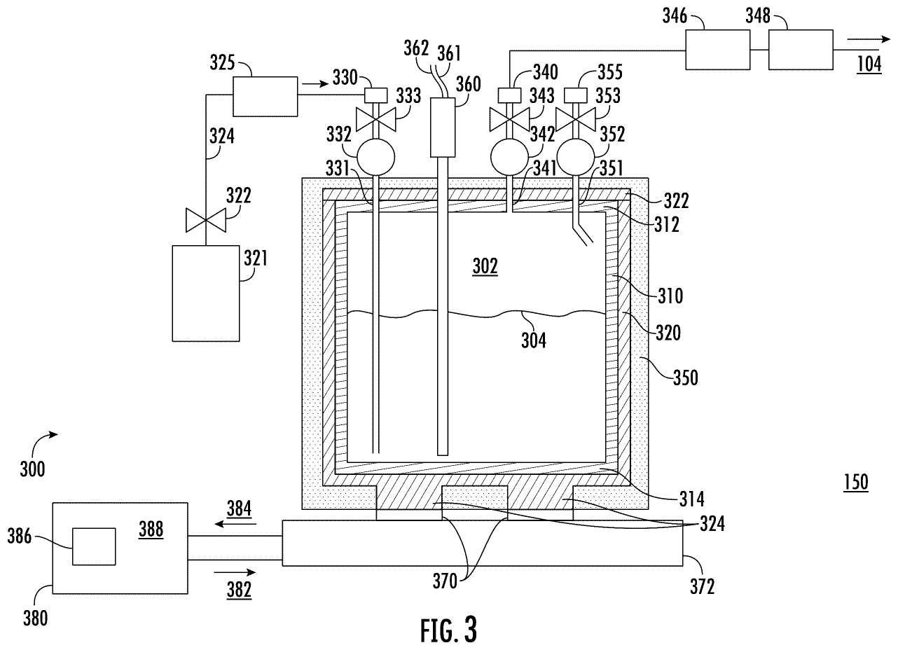

FIGS. 3-6 show the container assembly 300 according to some embodiments of the present disclosure. As shown in FIG. 3, the container assembly 300 is configured for storing a liquid precursor 304 in the interior 302 of a vessel 310 and for providing vaporized liquid precursor from the interior 302 of the vessel 310. The vessel includes an inlet conduit 331 for providing a carrier gas to the interior 302 of the vessel 310, an outlet conduit 341 for providing vaporized liquid precursor to the precursor supply conduit 104, and a probe member 360 for measuring the temperature of the liquid precursor 304 and/or the amount of liquid precursor 304 contained within the interior 302 of the vessel 310. The container assembly 300 is further configured to facilitate heat transfer between the liquid precursor 304 contained in the interior 302 of the vessel 310 and an external environment 150 outside of the container assembly 300. In this respect, the vessel 310 is surrounded, at least in part, by a jacket 320 that is affixed to and extends about the exterior of the vessel 310. The container assembly 300 may further include a thermal insulator 350, one or more thermoelectric heat pump 370, a heat sink 372, and a heat transfer circuit 380. Although shown and described herein as including certain elements and a having a specific arrangement, it is to be understood and appreciated that the container assembly 300 may include other elements and/or exclude certain elements described herein, or have another arrangement, and remain within the scope of the present disclosure.

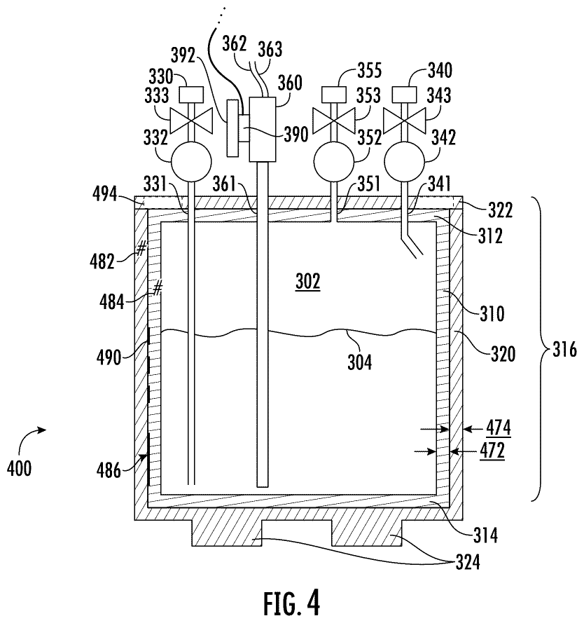

The vessel may generally be in the shape of a cylinder, having a bottom portion 314 and a top portion 312 that are connected by a cylindrical body 316 (shown in FIG. 4) to enclose an interior 302 for containing the liquid precursor 304. The vessel 310 is formed from a first material 484 (shown in FIG. 4) that is generally non-reactive to the liquid precursor 304. For example, the vessel 310 may be formed of a first material 484 that is resistant to corrosion form the liquid precursor 304 and/or does not contain trace impurities that may leach into the liquid precursor 304. Further, in some embodiments, the vessel 310 may comply to a U.S. Department of Transportation (DOT) regulation, such as 49 C.F.R. § 178 (2021). As such, the vessel 310 may be formed from a DOT 4B-compliant material. In certain embodiments, the vessel 310 may be formed from stainless steel, such as 316L stainless steel and/or 304L stainless steel. The volume of the interior 302 of the vessel 310 may vary in different embodiments of the disclosure. For example, the volume of the interior 302 of the vessel 310 may range from about 100 milliliters to about 19 liters, or more typically from about 500 milliliters to about 2,000 milliliters. The liquid precursor max fill volume is generally less that the volume of the interior of the vessel. Typically, the liquid precursor max fill volume is about 65% to about 85% of the volume of the interior of the vessel, or more typically about 70% to about 80% of the volume of the interior 302 of the vessel 310.

The inlet conduit 331 is seated in the top portion 312 of the vessel 310 and is in communication with the interior 302 of the vessel 310. The inlet conduit 331 may be configured for flowing a carrier gas into the interior 302 of the vessel 310, either through the liquid precursor 304 or over the surface of the liquid precursor 304. In this regard, the inlet conduit 331 may have one or more valves for opening and closing the inlet conduit 331 and for controlling the flow of the carrier gas into the vessel 310. For example, the inlet conduit 331 may have one or both of a manual valve 333 and an actuated valve 332 arranged on the exterior of the vessel 310 along the inlet conduit 331. The actuated valve 332 may be operably associated with the controller 120 (shown in FIG. 1) to control opening and closing of the inlet conduit 331. Further, the inlet conduit 331 may extend into the interior 302 towards the bottom portion 314 of the vessel 310. For example, the inlet conduit 331 may extend into the interior 302 of the vessel 310 to a depth that is just above the bottom portion 314 of the vessel 310 so that the carrier gas may be passed through the liquid precursor 304. Alternatively, the inlet conduit 331 may extend into the interior 302 of the vessel 310 towards the bottom portion 314 of the vessel 310 so that the carrier gas is passed over the surface of the liquid precursor 304.

A carrier gas mass flow controller (MFC) 325 is configured to provide a flow of a carrier gas to the vessel 310 from a carrier gas source 321. In this respect, the carrier gas source 321 is coupled to the inlet conduit 331 via a carrier gas supply conduit 324 with the carrier gas MFC 325 arranged thereon. The carrier gas MFC 325 may be operably associated with the controller 120 (shown in FIG. 1) to control the flow rate of the carrier gas to the vessel 310. The carrier gas may comprise, consist of, or consist essentially of an inert gas, such as, for example, nitrogen (N₂) or a noble gas (e.g., helium (He), argon (Ar), krypton (Kr)). It is also contemplated that the carrier gas may comprise one or more of hydrogen (H₂), ammonia (NH₃), or oxygen (O₂), which may be supplied neat or as a mixture with an inert gas.

The outlet conduit 341 is seated in the top portion 312 of vessel 310 and is in communication with the interior 302 of the vessel 310. The outlet conduit 341 is configured for providing vaporized liquid precursor from the interior 302 of the vessel 310 to the precursor supply conduit 104. In this regard, the outlet conduit 341 may comprise one or more valves for opening and closing the outlet conduit and for controlling the flow of the vaporized liquid precursor from the vessel 310. For example, the outlet conduit 341 may have one or both of a manual valve 343 and an actuated valve 342 arranged on the exterior of the vessel 310 along the outlet conduit 341. The actuated valve 342 may be operably associated with the controller 120 (shown in FIG. 1) to control opening and closing of the outlet conduit 341.

The vaporized liquid precursor may be entrained in a flow of the carrier gas exiting the vessel 310 of the container assembly 300 via the outlet conduit 341. A vapor pressure concentration sensor (VPCS) 346 and a vaporized liquid precursor MFC 348 may be arranged along the outlet conduit 341 and configured to provide vaporized liquid precursor 304 from the vessel 310 to the chamber arrangement 200 (shown in FIG. 1). In this regard, the VPCS 346 and the vaporized liquid precursor MFC 348 may be operably associated with the controller 120 (shown in FIG. 1) to control the flow rate of the vaporized liquid precursor to the chamber arrangement 200. The VPCS 346 may be configured to provide the measured vaporized liquid precursor concentration to the controller 120. The controller 120 may compare the measured concentration of the vaporized liquid precursor to a target vaporized liquid precursor concentration and adjust the vaporized liquid precursor MFC 348 so that the measured vaporized liquid precursor concentration measurement falls withing a predetermined differential from the target vaporized liquid precursor concentration.

The vessel may further comprise a refill conduit 351 that is seated in the top portion 312 of the vessel 310 and in communication with the interior 302 of the vessel 310. The refill conduit 351 may be configured for refilling the vessel 310 with liquid precursor 304. In this regard, the refill conduit 351 may have one or more valve for opening and closing the refill conduit 351 and for controlling the flow of the liquid precursor 304 into the vessel 310. For example, the refill conduit 351 may have one or both of a manual valve 353 and an actuated valve 355 arranged on the exterior of the vessel 310 along the refill conduit 351. The actuated valve 352 may be operably associated with the controller 120 (shown in FIG. 1) to control opening and closing of the refill conduit 351. Further, the refill conduit 351 may extend into the interior 302 towards the bottom portion 314 of the vessel 310. The refill conduit 351 may extend into the interior 302 towards the bottom portion 314 of the vessel 310 to a shallower depth than the inlet conduit 331 does. Further, in certain embodiments, the portion of the refill conduit 351 that extends into the interior of the vessel 310 may be bent towards the wall of the vessel 310 to reduce splashing and/or fluctuations in the liquid precursor level during refilling. Refilling of the vessel with the liquid precursor 304 may occur in a location that is remote from the semiconductor processing system 100 (shown in FIG. 1). For example, it is contemplated that the vessel 310 may be removed from the semiconductor processing system 100 so that the vessel 310 may be filled at a remote location, for example at a location outside of a cleanroom environment housing the semiconductor processing system 100 (shown in FIG. 1) like a local bulk refill station or at a chemical supplier site. Additionally, or alternatively, the refill conduit 351 may be fluidly connected to a bulk liquid precursor source that is in a location that is remote from the semiconductor processing system 100, such as, for example in a sub-fab, for refilling the vessel 310 without removing the vessel 310 from semiconductor processing system 100. In this regard, the vessel 310 may optionally have in inlet conduit quick connect 330, an outlet conduit quick connect 340, and a refill conduit quick connect 345 to easily separate the vessel 310 from the carrier gas supply conduit 324 and the precursor supply conduit 104, among other things (shown in FIG. 4).

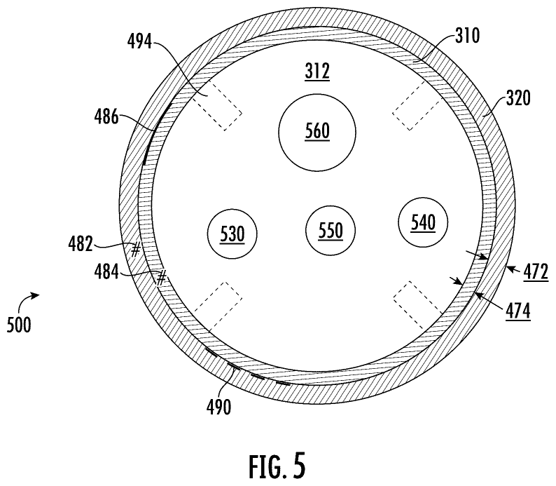

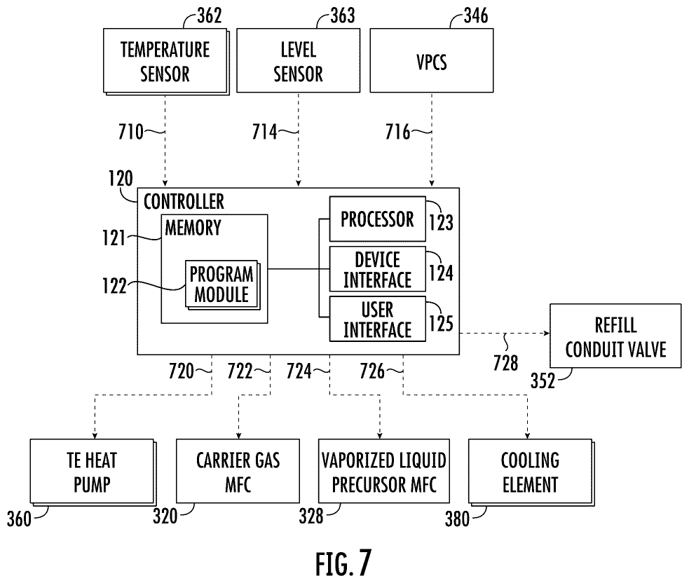

The probe member 360 is seated in the top portion 312 of the vessel 310 and extends into the interior 302 of the vessel 310 toward the bottom portion 314 of the vessel 310. In certain examples, the probe member 360 may be removably fixed within a probe member aperture 560 (shown in FIG. 5) so that the probe member 360 may be removed for cleaning or replacement as needed. The probe member 360 may contain one or more temperature sensor 362 that are operably associated with the controller 120 (shown in FIG. 1) and configured to provide the liquid precursor temperature measurement 710 (shown in FIG. 7) to the controller 120. Additionally, or alternatively, the controller 120 may contain one or more level sensor 363 that are operably associated with the controller 120 and configured to provide the liquid precursor level measurement 714 (shown in FIG. 7) to the controller 120. Although the probe member 360 is shown and described herein as including a certain number of temperature sensors 361 and/or the one or more level sensor 363, it is to be understood and appreciated that probe member 360 may include fewer or additional sensors of either type and such variations remain with the scope of the present disclosure.

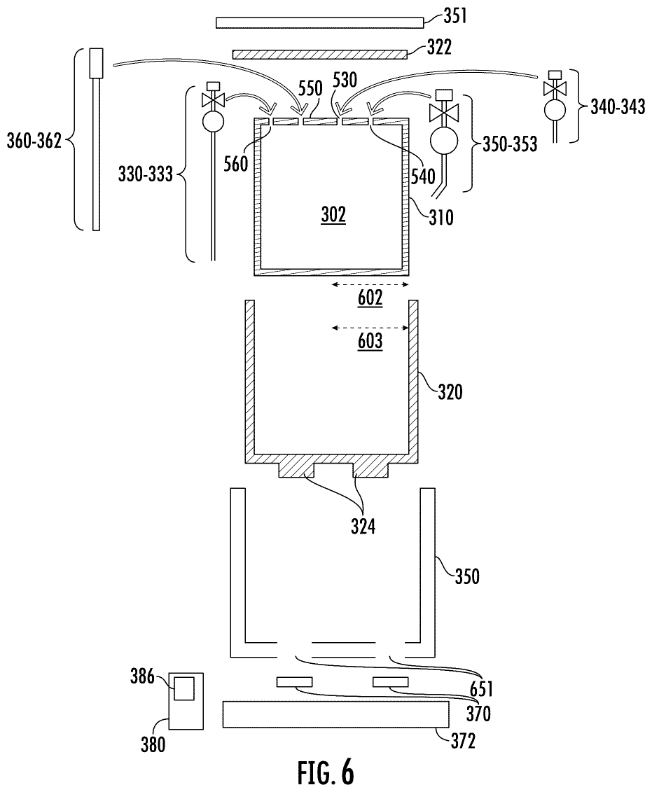

As shown in FIG. 5, the top portion 312 of the vessel 310 may have an outlet conduit aperture 530, an inlet conduit aperture 550, a refill conduit aperture 540, and a probe member aperture 560. The outlet conduit aperture 530 is configured to seat the outlet conduit 341 therein (shown in FIG. 6). The refill conduit aperture 540 is off set from the outlet conduit aperture 530 and is configured to seat the refill conduit 351 therein (shown in FIG. 6) such that the refill conduit 351 extends through the top portion 312 of the vessel 310 into the interior 302 of the vessel 310 (shown in FIG. 3). The inlet conduit aperture 550 is positioned between the outlet conduit aperture 530 and the refill conduit aperture 540 and is configured to seat the inlet conduit 331 therein (shown in FIG. 6) such that the inlet conduit 331 extends through the top portion 312 of the vessel 310 into the interior 302 of the vessel 310 (shown in FIG. 3). The probe member aperture 560 is offset from the outlet conduit aperture 530, the refill conduit aperture 540, and the inlet conduit aperture 550 and is configured to seat the probe member 360 therein such that the probe member 360 extends through the top portion 312 of the vessel 310 into the interior 302 of the vessel 310 (shown in FIG. 3). In addition to the various apertures, the top portion 312 of the vessel 310 may optionally have one or more protruding portion 494, extending from the top portion 312 of the vessel away from the interior 302 of the vessel 310 (shown in FIG. 4). The one or more protruding portion 494 may be configured to removably attach a handle for caring the vessel 310, a halo for protecting the values during transporting of the vessel 310, and/or the thermal insulator 350 (shown in FIG. 3) to the vessel 310. Although the top portion 312 of the vessel 310 is shown and described herein as having a certain arrangement of apertures for the various conduits and the probe member 360, it is to be understood and appreciated that other arrangements of apertures, including having fewer or additional apertures, is possible and such variations remain with the scope of the present disclosure. Similarly, it is to be understood and appreciated that other arrangements of the one or more protruding portion 494 are possible, including excluding the one or more protruding portion 494, and such variations remain with the scope of the present disclosure.

Referring once again to FIG. 4 and with continuing reference to FIG. 5, the jacket 320 surrounds or otherwise extends, at least in part, about the exterior of the vessel 310. For example, the jacket 320 may extend about the cylindrical body 316 and the bottom portion 314 of the vessel 310. In some embodiments, the jacket 320 may optionally extend about the top portion 312 of the vessel 310 (shown by 322 in FIG. 4). It is contemplated that the jacket 320 be formed from a second material 482 having a thermal conductivity greater than the thermal conductivity of the first material 484 forming the vessel 310. In other words, the vessel 310 is formed of a first material 484 having a first thermal conductivity and the jacket is formed form a second material 482 having a second thermal conductivity that is greater than the first thermal conductivity. For example, as discussed above, the vessel 310 may be formed from a first material 484 that is non-reactive to the liquid precursor 304 and additionally may be DOT 4B-compliant. In certain embodiments, the vessel 310 may be formed from stainless steel, such as 316L stainless steel and/or 304L stainless steel. While stainless steel is generally non-reactive to the liquid precursor 304, its thermal conductivity is relatively low (e.g., about 16 W/mK at 25 degrees Celsius). To compensate (at least in part) for the relatively low thermal conductivity of the first material 484, the jacket 320 is made from the second material 482 with a higher thermal conductivity to facilitate heat transfer from the liquid precursor 304 contained within the interior 302 of the vessel 310 to the external environment 150 outside of the container assembly 300. In certain embodiments, the jacket 320 may be formed from an aluminum-containing material, such as 6060 aluminum, 6061 aluminum, and/or 6063 aluminum. The thermal conductivity of aluminum varies depending upon the composition of the specific alloy, but generally ranges from about 160-210 W/mK at 25 degrees Celsius.

The jacket 320 is affixed to the vessel 310 using an interference fit 486. The interference fit may be such that either (or both) the vessel 310 and the jacket 320 deviate in size relative to its respective nominal dimensions (e.g., the dimensions when the part are separated so as to be dimensionally unconstrained relative to the other while at room temperature), thereby creating interference between the vessel 310 and the jacket 320. For example, in some embodiments, the diameter of the jacket 320 may deviate its nominal diameter when the jacket 320 and vessel 310 are separated and are at room temperature. Additionally, or alternatively, in some embodiments, the diameter of the vessel 310 may deviate from its nominal diameter when the vessel 310 and jacket 320 are separated and at room temperature. A portion of the interference fit 486 is pictorially shown in FIGS. 3 and 4 at the interface between the vessel 410 and the jacket 420; however, as will be appreciated by one of skill in the art, the interference fit may be over entire interface between the vessel 310 and the jacket 320. Advantageously the interference fit 486 results in a high degree of contact between the jacket 320 and the vessel 310, limiting resistance to heat flow between the vessel 310 and the jacket 320. As will be appreciated by those of skill in the art in view of the present disclosure, limiting thermal resistance between the vessel 310 and the jacket 320 may in turn increase heat transfer between a liquid precursor 304 contained within the interior 302 of the vessel 310 and an external environment 150 outside the container assembly 300, enabling use of a material having relatively low thermal conductivity to form the vessel 310, for example, the second material 482.

The degree of interference in the interference fit 486 between the vessel 310 and the jacket 320 may vary in different embodiments of the disclosure. The degree of interference may be expressed as the difference between the outer radius of the inner part (e.g., an outer diameter of the vessel 310) and the inner radius of the outer part (e.g., an inner diameter of the jacket 320) when the parts are separated so as to be dimensionally unconstrained relative to one another at room temperature. It is contemplated that the degree of interference within the interference fit 486 between the vessel 310 and the jacket 320 may be at least about 0.005 millimeters and no more than about 0.345 millimeters, typically at least about 0.023 millimeters and no more than about 0.345 millimeters, or at least about 0.074 millimeters and no more than about 0.345 millimeters. In some embodiments, the degree of interference within the interference fit 486 between the vessel 310 and the jacket 320 may be at least about 0.005 millimeters and no more than about 0.071 millimeters, or at least about 0.005 millimeters and no more than about 0.048 mm, or at least about 0.023 millimeters and no more than about 0.089 millimeters, or at least about 0.046 millimeters and no more than about 0.089 millimeters. Such levels of interference may generally be obtained by press fitting the jacket 320 and the vessel 310 together by hand or using mechanical force. In other embodiments, the degree of interference within the interference fit 486 between the vessel 310 and the jacket 320 may be at least about 0.074 millimeters to no more than about 0.346 millimeters, or at least about 0.074 millimeters and no more than about 0.229 millimeters, or at least about 0.074 millimeters and no more than about 0.178 millimeters, or at least about 0.074 millimeters and no more than about 0.140 millimeters, or at least about 0.074 millimeters and no more than about 0.112 millimeters, or at least about 0.112 millimeters and no more than about 0.345 millimeters, or at least about 0.112 millimeters and no more than about 0.241 millimeters, or at least about 0.112 millimeters and no more than about 0.229 millimeters, or at least about 0.112 millimeters and no more than about 0.178 millimeters, or at least about 0.163 millimeters and no more than about 0.345 millimeters, or at least about 0.163 millimeters and no more than about 0.241 millimeters, or at least about 0.163 millimeters and no more than about 0.229 millimeters. Such levels of interference may generally be obtained by shrink fitting the vessel 310 and the jacket 320 together, for example, by heating the jacket 320 to increase its dimensions compared to its nominal dimensions (e.g., when the parts are separated and are at room temperature) and/or by cooling the vessel 310 to shrink its dimensions compared to its nominal dimensions such that the two parts can be joined. Increasing the degree of interference within the interference fit 486 results in a higher degree of contact between the jacket 320 and the vessel 310 and may further extend the lifetime of the container assembly 300. As the temperature of the container assembly 300 is cycled, the degree of interference within the interference fit 486 between the jacket 320 and the vessel 310 may decrease. Thus, having a high degree of interference within the interference fit 486 on a newly manufactured container assembly 300 may increases the lifetime of the container assembly 300 by extending the number of cycles that have an acceptable interference in the interference fit 486 and therefore an acceptable heat transfer between the liquid precursor 304 contained within the interior 302 of the vessel 310 and the external environment 150.

In addition to the difference in the thermal conductivity between the first material 484 of the vessel 310 and the second material 482 of the jacket 320 and the degree of interference with the interference fit 486 between the two, the wall thickness 472 of the jacket 320 (shown in FIG. 5), relative to the wall thickness 474 of the vessel 310 may be used to further facilitate heat transfer between the liquid precursor 304 contained within the interior 302 of the vessel 310 and the external environment 150. In this regard, the wall thickness 472 of the jacket 320 is generally greater than the wall thickness of the vessel. In certain embodiments, the container assembly 300 (e.g., the wall thickness 474 of the vessel 310) may comply with a U.S. Department of Transportation regulation, such as 49 C.F.R. § 178 (2021). For example, the wall thickness 474 of the vessel 310 may be between about 2 millimeters and about 10 millimeters, or between about 3 millimeters and about 8 millimeters, or even between about 3 millimeters and about 6 millimeters. Advantageously, thicknesses within these ranges can provide compliance with the aforementioned DOT regulation while limiting the handicap otherwise potentially presented by the relatively low thermal conductivity of the first material 484 forming the vessel 310.

The wall thickness 472 of the jacket 320 may be greater than the wall thickness 474 of the vessel 310, although embodiments where the wall thickness 474 of the of the jacket 320 is equal to or less than the wall thickness 474 of the vessel 310 are included within the scope of the disclosure. For example, the wall thickness 472 of the jacket 320 310 may be between about 2 millimeters and about 20 millimeters, or between about 4 millimeters and about 15 millimeters, or even between about 4 millimeters and about 10 millimeters. Advantageously, jacket wall thicknesses within these ranges may cooperate with the vessel wall thickness to provide compliance with the aforementioned DOT regulation and/or provide sufficient thermal mass to compensate (at least in part) with the relatively thermal conductivity of the first material 484 forming the vessel 310.

In certain embodiments, the container assembly 300 may optionally include a thermal compound 490 disposed between the jacket 320 and the vessel 310 at the interface of the two. The thermal compound 490 is pictorially shown in FIGS. 3 and 4 at the interface between the vessel 410 and the jacket 420; however, the thermal compound 490 may disposed between the vessel 310 and the jacket 320 across the interface between the two as a continuous or discontinuous layer. The thermal compound 490 may be used to increase the degree of contact between the jacket 320 and the vessel 310. As such, the thermal compound 490 may allow for a lower degree of interference within the interference fit 486 between the vessel 310 and the jacket 320, which may simplify the manufacturing process of the container assembly 300. Examples of suitable thermal compounds (or thermal paste) include silicone oil base compounds such as 120 Series Thermal Joint Compound, available from Wakefield Thermal, Inc. of Nashua, New Hampshire.

With continuing reference to FIG. 3, the thermal insulator 350, the one or more thermoelectric heat pump 370, the heat sink 372, and the heat transfer circuit 380 are configured to transfer heat between the liquid precursor 304 contained within the interior 302 of the vessel 310 and the external environment 150. The thermal insulator 350, at least in part, surrounds or extends about the jacket 320 and vessel 310 insulating the surrounded portions from the external environment 150. In some embodiments, the thermal insulator 350 surrounds the cylindrical body 316 and the bottom portion 314 of the vessel 310 and the jacket 320 and is separated from the vessel 310 by the jacket 320. The thermal insulator 350 may also surround the top portion 312 of the vessel 310 (shown in FIG. 6). The various conduits (e.g., the inlet conduit 331, the outlet conduit 341, and the refill conduit 351) and the probe member 360 extend from the top portion 312 of the vessel 310 through the thermal insulator 350. The thermal insulator 350 may optionally be fixed to the vessel 310 by attaching the thermal insulator 350 to the one or more protruding portion 494 positioned on the top portion 312 of the vessel 310. The jacket 420 may also include one or more protruding portion 424 that extend through the thermal insulator 350. For example, the jacket 320 may include one or more protruding portion 424 extending from the bottom of the jacket 320, in a direction opposite to the outlet conduit 341, through the thermal insulator 350. In the illustrated example the jacket 320 has two protruding portions 424 both extending from the bottom of the jacket 320 and in a direction opposite to the outlet conduit 341 through 651 (shown in FIG. 6) the thermal insulator 350. Examples of suitable thermal insulators include Thermal Wrap™ Aerogel Blankets, available from the Cabot Corporation of Boston, Massachusetts.

The vessel 310 and jacket 320 may be in thermal communication with the heat sink 372 and the heat transfer circuit 380 via the one or more thermoelectric heat pump 370. In this regard, the one or more protruding portion 424 of the jacket 320 may be in direct contact with one or more thermoelectric heat pump 370, which in turn are in contact with the heat sink 372. In the illustrated example, the jacket 320 has two protruding portions 424, each of which are in contact with a thermoelectric heat pump 370. The one or more thermoelectric heat pump 370 is (are) in turn in contact (e.g., direct mechanical contact) with the heat sink 372.

The heat sink 372 is in thermal communication with the heat transfer circuit 380. In this regard, the heat transfer circuit 380 is configured to provide a heat transfer medium 388, using a mechanical circulator 386, to and from the heat sink 372. In certain embodiments, the heat transfer circuit 380 may include a heat transfer medium supply conduit 382 and a heat transfer medium return conduit 384 for passing a heat transfer medium 388 through and/or around the heat sink 372. In certain examples, the heat transfer medium 388 may comprise, consist of, or consist essentially of air. In certain other examples, the heat transfer medium 388 may comprise, consist of, or consist essentially of water. In certain other examples, the heat transfer medium 388 may comprise, consist of, or consist essentially of glycol and/or alcohol. In certain other examples, the heat transfer medium 388 may comprise, consist of, or consist essentially of a perfluorinated coolant. Examples of suitable coolants include Fluorinert®, available from the 3M Company of Maplewood, Minnesota.

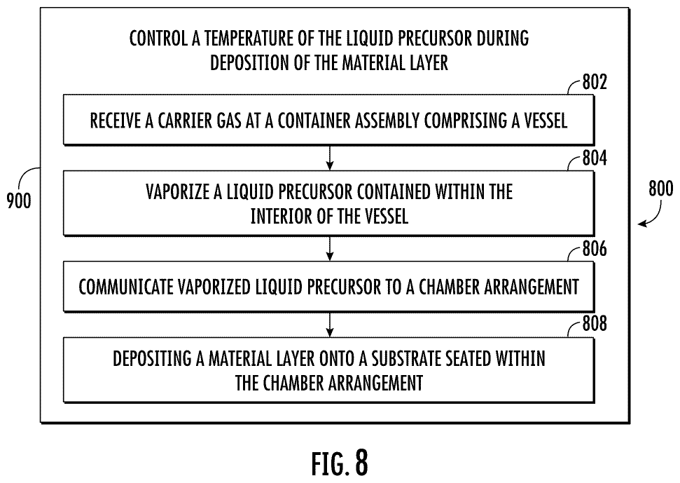

Each of the one or more thermoelectric heat pump 370 may be configured to throttle (e.g., increase or decrease) heat transfer between the liquid precursor 304 contained within the interior 302 of the vessel 310 and the heat transfer medium 388, which in turn transfers heat to or from the external environment 150. In this respect, the one or more thermoelectric heat pump 370 may be operatively associated with the controller 120 (shown in FIG. 1) to throttle heat transfer between the liquid precursor 304 contained within the interior 302 of the vessel 310 and the external environment 150 using a drive current 720 (shown in FIG. 8) provided to the one or more thermoelectric heat pump 370 by the controller 120. In some embodiments, the one or more thermoelectric heat pump 370 are configured to throttle heat transfer from the liquid precursor 304 contained within the interior 302 of the vessel 310 to the external environment 150. In other embodiments, the one or more thermoelectric heat pump 370 are configured to throttle heat transfer to the liquid precursor 304 contained within the interior 302 of the vessel 310 from the external environment 150.

With continuing reference to FIG. 4, it is contemplated that thermoelectric heat pump 370 and the heat sink 372 may be a first thermoelectric heat pump 370 and a first heat sink 372, respectively, and that the container assembly 300 may further include one or more second thermoelectric heat pump 390 and one or more second heat sink 392. In such examples the one or more thermoelectric heat pump 370 may be mechanically coupled to a structure protruding into the liquid precursor 304 contained within the container assembly 300, for example through the probe member 360 and/or the inlet conduit 331, and in turn couple the one or more second heat sink 392 to the structure protruding into the liquid precursor 304 contained within the container assembly 300. So coupled, the one or more second thermoelectric heat pump 390 may be configured to transfer heat between the liquid precursor 304 and the external environment 150, for example to supplement transfer of heat transferred using the first thermoelectric heat pump 370. Advantageously, this exploits the available surface area of the structure protruding into the liquid precursor 304, increasing the rate at which heat may be transferred between the liquid precursor 304 and the external environment 150.

In certain examples the one or more second thermoelectric heat pump 392 may be directly connected to the structure protruding into the liquid precursor 304, for example without an intermediate piece part or coolant circuit. In this respect it is contemplated that the one or more second thermoelectric heat pump 392 may be directly connected to the probe member 360 and thermally coupled therethrough to the liquid precursor 304. In accordance with certain examples, the protruding structure (e.g., the probe member 360) may operate as a cold finger immersed within the liquid precursor 304, enhancing cooling and/or temperature control of the liquid precursor 304. In accordance with certain examples, the protruding structure (e.g., the probe member 360) may operate as a hot finger immersed within the liquid precursor, enhancing heating and/or temperature control of the liquid precursor 304. It is also contemplated that the second thermoelectric heat pump 390 may operate both as a cold finger at certain times and as a hot finger at other times to alternatively heat and cool the liquid precursor 304, as appropriate according environmental conditions within the container assembly 300 during usage of the charge of liquid precursor 304 contained within the container assembly 300.

Referring to FIG. 7, the controller 120 is shown according to an example of the present disclosure schematically showing inputs to and output from the controller 120 to the container assembly 300 (shown in FIG. 1). In the illustrated example, the controller 120 is in communication with the probe member 360 and therethrough with one or more temperature sensor 362 and the level sensor 363 to receive the liquid precursor temperature measurement 710 and the liquid precursor level measurement 714 therefrom, respectively. The controller 120 may also be in communication with the VPCS 346 to receive therefrom the precursor concentration measurement 716. As will be appreciated by those of skill in the art in view of the present disclosure, the controller 120 may be in communication with fewer and/or other sensors than shown and described herein and remain within the scope of the present disclosure.

In certain examples, the controller 120 may compare a liquid precursor temperature measurement 710 to a predetermined liquid precursor temperature that is recorded in one of the program modules 122 recorded on the memory 121. When the differential between the measured and predetermined liquid precursor temperature exceeds a predetermined liquid precursor temperature differential, also recorded in one of the program modules 122, the controller 120 may throttle (e.g., increase or decrease) rate of heat transfer between the liquid precursor 304 (shown in FIG. 3) and the external environment 150 (shown in FIG. 3). Throttling may be accomplished by applying a drive current 720 to the one or more thermoelectric heat pump 370. The direction and the magnitude of the applied drive current is adjusted by the controller (using a power source operatively associated with the controller 108) to minimize a temperature differential between the measured temperature 710 of the liquid precursor 304 and a target temperature of the liquid precursor 304. Additionally, or alternatively, throttling may be accomplished by adjusting the flow rate and/or the temperature of the heat transfer medium 388 from the heat transfer circuit 380 traversing the heat sink 372. When a differential between the liquid precursor 304 temperature measurement 710 and the predetermined precursor temperature is less than a predetermined precursor temperature differential, the controller 120 may leave the rate of heat transfer unchanged, and precursor temperature monitoring may continue.

In certain embodiments, the controller 120 may compare the liquid precursor level measurement 714 to a predetermined liquid precursor value that is recorded on one of the of program modules 122 recorded on the memory 121. When the liquid level is less than the predetermined liquid level value, the controller 120 may provide a user output to a user interface 125, for example to alert a user of a need to replace or refill the container assembly 300 (shown in FIGS. 3-6). In accordance with certain other embodiments, the controller 120 may send a signal to open the refill conduit actuated valve 355 to refill the vessel 310 with liquid precursor 304 from a bulk liquid precursor source.

In certain examples, the controller 120 may offset the predetermined liquid precursor temperature using the liquid precursor level measurement 714. Additionally, or alternatively, the controller 120 may adjust the liquid precursor temperature measurement 710 using the liquid precursor level measurement 716. As will be appreciated by those of skill in the art in view of the present disclosure, this can limit the risk that throttling of the rate of heat transfer between the liquid precursor 304 (shown in FIG. 3) and the external environment 150 (shown in FIG. 3) overshoots the predetermined liquid precursor temperature due to difference in thermal mass of vaporized liquid precursor.

In accordance with FIGS. 8 and 9, a material layer deposition method 800 is shown according to some embodiments of the present disclosure. The material layer deposition method 800 may be performed using a semiconductor processing system 100 (shown in FIG. 1). As shown in FIG. 8, the method 800 includes receiving a carrier gas at a container assembly 300 (shown in FIG. 1), as shown with box 802. The container assembly 300 according to various embodiments of the present disclosure is shown FIGS. 1-6 and described above. The container assembly 300 includes a vessel 310 (shown in FIG. 3) that is formed from a first material 484 (shown in FIG. 4) that has a first thermal conductivity and a jacket 320 (shown in FIG. 3) that is affixed to the vessel 310 with an interference fit and extends, at least in part, about the exterior of the vessel 310. The jacket 320 is formed from a second material 482 (shown in FIG. 4) that has a second thermal conductivity, wherein the second thermal conductivity greater than the first thermal conductivity. The carrier gas is received through the inlet conduit 331 (shown in FIG. 3) that is seated in the vessel 310 and in communication with an interior 302 (shown in FIG. 3) of the vessel 310. The receiving of the carrier gas at the container assembly 300, may further include controlling the temperature of a liquid precursor 304 (shown in FIG. 3) contained within the interior 302 (shown in FIG. 3) of the vessel 310, shown with box 900. The method 800 also includes, vaporizing the liquid precursor 304 that is contained in the interior 302 of the vessel 310, shown with box 804. Vaporizing the liquid precursor 304 includes transferring heat between the liquid precursor 304 and an external environment 150 (shown in FIG. 3), outside of the container assembly 300 through the vessel 310 and the jacket 320. Vaporizing the liquid precursor 304 may further include controlling the temperature of the liquid precursor 304 contained within the interior 302 of the vessel 310, as shown with box 900. The method 800 also includes, communicating vaporized liquid precursor to a chamber arrangement 200 (shown in FIG. 1), as shown with box 806. The vaporized liquid precursor is provided from an outlet conduit 341 (shown in FIG. 3), seated in the vessel 310 and in communication with an interior 302 of the vessel 310, to the chamber arrangement 200. In certain embodiments, the chamber arrangement 200 has a single-wafer cross-flow configuration (for example, as shown in FIG. 2) and as described above. Communicating the vaporized liquid precursor to the chamber arrangement 200 may further include controlling the temperature of the liquid precursor 304 contained within the interior 302 of the vessel 310, as also shown with block 900. The method also includes depositing a material layer 216 (shown in FIG. 1) onto a substrate 214 (shown in FIG. 1) seated within the chamber arrangement 200, as shown with box 808. The material layer 216 is deposited onto the substrate 214 by exposing the substrate 214 to the vaporized liquid precursor. Depositing a material layer 216 onto a substrate 214 seated within the chamber arrangement 200 may further include controlling the temperature of the liquid precursor 304 contained within the interior 302 of the vessel 310, as further shown with box 900.

As shown in FIG. 9, controlling 900 the temperature of the liquid precursor 304 contained within the interior 302 of the vessel 310 may be accomplished by receiving a liquid precursor temperature measurement, e.g., the liquid precursor temperature measurement 710 (shown in FIG. 7), as shown with box 910. In this respect the liquid precursor temperature measurement 710 may be received by a controller 120 (shown in FIG. 7) that is in communication with one or more temperature sensor 362 (shown in FIG. 3) in a probe member 360 (shown in FIG. 3) seated in the vessel 310 and extending into the interior 302 of the vessel 310 into the liquid precursor 304. Controlling 900 temperature of the liquid precursor may also include calculating the differential between a predetermined temperature value and the received liquid precursor temperature measurement 710, as shown with box 920. The target temperature value may be stored in a program module in one of the program modules 122 (shown in FIG. 7) recorded on the memory 121 (shown in FIG. 7) of the controller 120. When the differential between the measured and predetermined liquid precursor temperature exceeds a predetermined liquid precursor temperature differential, also recorded in one of the program modules 122, a rate of heat transfer between the liquid precursor 304 and an external environment 150 may be throttled, as shown with box 940. Throttling may be accomplished by applying a drive current 720 (shown in FIG. 7) to the one or more thermoelectric heat pump 370 (shown in FIG. 3). The direction and the magnitude of the drive current 720 is adjusted by the controller 120 (using a power source operatively associated with the controller 120) to minimize a temperature differential between the measured temperature 710 of the liquid precursor 304 and a target temperature of the liquid precursor 304. Additionally, or alternatively, throttling may be accomplished by adjusting the flow rate and/or the temperature of the heat transfer medium 388 (shown in FIG. 3) from the heat transfer circuit 380 (shown in FIG. 3) traversing the heat sink 372 (shown in FIG. 3). The throttling may continue until the differential between the liquid precursor temperature measurement 710 and the predetermined precursor temperature is less than a predetermined precursor temperature differential. After the throttling, the operations for controlling the liquid precursor temperature may be continued, as shown with arrow 950. When the differential between the liquid precursor temperature measurement 710 and the predetermined precursor temperature is less than the predetermined precursor temperature differential, the controller 120 may leave the rate of heat transfer unchanged and the operations for controlling the liquid precursor temperature 900 may be continued, as shown with arrow 960.

With reference to FIG. 10, a method for making a container assembly, e.g., the container assembly 300 (shown in FIG. 1), is shown. The method 1000 includes forming a vessel from a first material having a first thermal conductivity, e.g., forming the vessel 310 (shown in FIG. 3) from the first material 484 (shown in FIG. 4); and seating a conduit in the vessel, e.g., the outlet conduit 341 (shown in FIG. 3); as shown with box 1010 and box 1020. The method 1000 also includes forming a jacket from a second material having a second thermal conductivity, e.g. forming the jacket 320 (shown in FIG. 3) from the second material 482 (shown in FIG. 4); and arranging the vessel in the jacket; as shown with box 1030 and box 1040. It is contemplated that the method 1000 further include affixing the jacket to the vessel with an interference fit, e.g., the interference fit 486 (shown in FIG. 4), as shown with box 1060. Although shown and described herein as including certain operations it is to be understood and appreciated that the method 1000 may include additional operations, and/or omit operations shown and described herein, and remain within the scope of the present disclosure.

Forming 1010 the vessel may include forming the vessel in the shape of a cylinder, as also shown with box 1010. In this respect the vessel may be formed within a bottom portion and a top portion connected by a cylindrical body, e.g., the bottom portion 314 (shown in FIG. 3) and the top portion 312 (shown in FIG. 3) connected by the cylindrical body 316 (shown in FIG. 3), as further shown with box 1010. The vessel may be formed to enclose an interior of the vessel to contain a liquid precursor, e.g., to enclose the interior 302 (shown in FIG. 3) for containing the liquid precursor 304 (shown in FIG. 3), as additionally shown with box 1010. It is contemplated that the first material may be non-reactive to the liquid precursor and/or that the first material may cooperate with features of the container assembly (e.g., dimensioning and assembly) to render the container assembly DOT 4B-compliant, as further shown with box 1010. In certain embodiments the first material may include (or consist or consist essentially of) a stainless steel material, such as 316L stainless steel or 304L stainless steel.

Seating 1020 the conduit in the vessel may include seating one or more of the outlet let conduit, a refill conduit and a carrier gas conduit in the vessel; e.g., one or more of the refill conduit 351 (shown in FIG. 3), the carrier gas supply conduit 324 (shown in FIG. 3), and the outlet conduit 341 (shown in FIG. 3), as also shown with box 1020. The conduit may be seated such that the conduit is in communication with the interior of the vessel, for example with an ullage space defined above a liquid precursor charge contained within the vessel or within the liquid precursor charge itself, as further shown with box 1020. Seating 1020 may also include seating a probe member in the vessel, e.g., the probe member 360 (shown in FIG. 10), as additionally shown with box 1020. In this respect it is contemplated that the probe member may be seated in the vessel such that the probe member extends through both an ullage space defined within the vessel and into the liquid precursor contained with the vessel, for example to acquire one or more of temperature of vaporized liquid precursor and/or liquid precursor as well as level of the liquid precursor within the vessel, as also shown with box 1020.

Forming 1030 the jacket from the second material may include forming the jacket from a second material having a second thermal conductivity greater than the first thermal conductivity of the first material, as also shown with box 1030. The second material may be (e.g., consist of or consist essentially of) an aluminum-containing material, as further shown with box 1030. In this respect the second material may be selected from a group including 6060 aluminum, 6061 aluminum, and 6063 aluminum, as additionally shown with box 1030. Forming 1030 the jacket may include forming the jacket with an open top and a sealed bottom coupled to one another by an intermediate portion, as also shown with box 1030. Forming 1030 the jacket may include forming the jacket with one or more protruding portion extending from the sealed bottom in a direction opposite the open top of the jacket, as further shown with box 1030.

Arranging 1040 the vessel in the jacket may include arranging the vessel in the jacket such that the jacket extends (at least in part) about the exterior of the vessel, as also shown with box 1040. Arranging 1040 the vessel in the jacket may include bring a lower surface of the vessel into contact with an inner surface of the base of the jacket, as further shown with box 1040. Arranging 1040 the vessel in the jacket may include coating either (or both) an exterior of the vessel and an interior of the jacket with a thermal compound, e.g., the thermal compound 490 (shown in FIG. 4), as further shown with box 1040. Advantageously, in addition to limiting thermal resistance between the vessel and the jacket, the thermal paste may facilitate assembly of the container assembly, for example by limiting friction between the vessel and the jacket during arrangement of the jacket about the vessel and/or the affixing 1060 of the jacket to the vessel with the aforementioned interference fit.

Affixing 1060 the vessel in the jacket may include heating the jacket such that the actual dimensions of the jacket are increased relative to dimensions of the jacket at room temperature (e.g., nominal dimensions of the jacket when separate from the jacket at room temperature), thereafter arranging 1040 the vessel in the heated jacket, and allowing the jacket to then cool to form the interference fit, as shown with box 1060. For example, the jacket may be heated to a temperature that is between about 20 degrees Celsius and about 100 degrees Celsius, or between about 20 degrees Celsius and about 200 degrees Celsius, or even between about 20 degrees and about 500 degrees Celsius, and the vessel thereafter arranged in the jacket while warm relative to the jacket. It is also contemplated that affixing 1060 the jacket to the vessel may include heating the jacket prior to arranging 1040 the vessel in the jacket, as further shown with box 1060. Advantageously, heating the jacket prior to arranging the vessel in the jacket enables the jacket to be formed with a relatively large nominal interference relative to the vessel, enabling the interference fit to be tighter than otherwise possible. As will be appreciated by those of skill in view of the present disclosure, increased tightness reduces resistance to heat transfer between the vessel the jacket, simplifying temperature control of the vessel the liquid precursor contained in the vessel.

Affixing 1060 the vessel in the jacket may include cooling the vessel such that the actual dimensions of the vessel are decreased relative to dimension of the vessel at room temperature (e.g., nominal dimensions of the vessel when separated from the vessel and at room temperature), thereafter arranging 1040 the vessel in the jacket, and then allowing the vessel to warm to room temperature to form the interference fit, as also shown with box 1060. For example, the vessel may be cooled to a temperature that is between about 20 degrees Celsius and about-100 degrees Celsius, or between about 20 degrees Celsius and about-150 degrees Celsius, or even that is between about 20 degrees Celsius and about-200 degrees Celsius, and vessel thereafter arranged in the jacket while cool relative to the jacket. It is also contemplated that affixing 1060 the jacket to the vessel may include cooling the vessel prior to arranging 1040 the vessel in the jacket, as further shown with box 1060. It is further contemplated that affixing 1060 the jacket to the vessel may include both heating the jacket and cooling the vessel prior to arranging the vessel in the jacket, as further shown with box 1060. The vessel may then be permitted to warm and the jacket permitted to cool, for example, to a common equilibrium temperature, to form an interference fit between the vessel and the jacket, for example to room temperature, as additionally shown with box 1060. As will be appreciated by those skill in the art in view of the present disclosure, using both jacket heating and vessel cooling enables the vessel and/or the jacket to be formed with a relatively large interference, the resulting thereby being greater than otherwise possible in examples where only one of the vessel and the jacket is dimensionally changed via heating or cooling prior to arranging the vessel in the jacket.

In some embodiments, the arranging 1040 the vessel in the jacket and affixing 1060 the jacket to the vessel may occur simultaneously, as shown with box 1070. For example, the jacket 320 may be arranged about the vessel 310 by press fitting the jacket about the vessel or the vessel into the jacket, such as by applying force by hand or by use of a mechanical device like a press, as also shown with bracket 1070. Press fitting may be performed with the jacket and the vessel at room temperature. Alternatively, press fitting may be performed when the jacket is at an elevated temperature and/or the vessel is at a reduced temperature relative to one another or room temperature, and remain within the scope of the present disclosure. In certain examples the vessel may be clamped in the jacket, for example by pressure the top of the vessel against the bottom of the jacket such that residual compressive force exists between a lower wall of the vessel and a lower wall of the jacket once the interference fit is formed, further limiting heat transfer between the vessel and the jacket, as further shown with box 1040.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

1. A container assembly, comprising:
a vessel formed from a first material having a first thermal conductivity;
a conduit seated in the vessel and in communication with an interior of the vessel; and
a jacket extending about the vessel and formed from a second material having a second thermal conductivity,
wherein the second thermal conductivity is greater than the first thermal conductivity, and
wherein the jacket is affixed to the vessel with an interference fit to limit resistance to heat flow between the vessel and the jacket.

2. The container assembly of claim 1, wherein the conduit is first conduit and the container assembly further comprises:
a second conduit seated in the vessel and in fluid communication with the interior of the vessel, the second conduit extending into the interior of the vessel a distance greater than the first conduit; and
a third conduit seated in the vessel and in fluid communication with the interior of the vessel, the third conduit extending into the interior of the vessel to a location beyond the second conduit.

3. The container assembly of claim 2, wherein the first conduit has a first manual valve and a first actuated valve arranged therealong, wherein the second conduit has a second manual valve and a second actuated valve arranged therealong, and wherein the third conduit has a third manual valve and a third actuated valve arranged therealong.

4. The container assembly of claim 1, further comprising a probe member seated in the vessel and extending into the interior of the vessel, wherein the probe member comprises a temperature sensor and one or more level sensor.

5. The container assembly of claim 1, wherein the vessel is formed from a stainless steel material, and wherein the jacket is formed from an aluminum-containing material.

6. The container assembly of claim 1, wherein an interference between the vessel and the jacket is between about 0.005 millimeters and about 0.345 millimeters.

7. The container assembly of claim 1, further comprising:
a thermoelectric heat pump coupled to the jacket;
a heat sink coupled to the thermoelectric heat pump; and
a heat transfer circuit connected to the heat sink.

8. The container assembly of claim 7, wherein the thermoelectric heat pump is a first thermoelectric heat pump and wherein the container assembly further comprises one or more second thermoelectric heat pump coupled to the jacket, wherein the heat sink is coupled to the one or more second thermoelectric heat pump.

9. The container assembly of claim 7, wherein the second thermoelectric heat pump is connected to a probe member seated in the vessel and thermally coupled therethrough to an interior of the container assembly.

10. The container assembly of claim 7, wherein the jacket has one or more protruding portion extending in a direction opposite the conduit, and wherein the thermoelectric heat pump is coupled to the one or more protruding portion of the jacket.

11. The container assembly of claim 9, wherein the one or more protruding portion is a first protruding portion and a second protruding portion spaced apart from the first protruding portion, wherein the thermoelectric heat pump is a first thermoelectric heat pump seated on the first protruding portion, and further comprising a second thermoelectric heat pump seated on the second protruding portion.

12. The container assembly of claim 1, further comprising a thermal insulator extending about the jacket and separated from the vessel by the jacket.

13. The container assembly of claim 1, further comprising a liquid precursor contained within the interior of the vessel.

14. The container assembly of claim 13, wherein the liquid precursor is selected from the group consisting of a silicon-containing precursor, germanium-containing precursor, a phosphorous-containing precursor, and an arsenic-containing precursor.

15. A chamber arrangement, comprising:
a chamber body having a horizontal crossflow arrangement; and
a container assembly as recited in claim 1 supported above the chamber body, wherein the first material is a stainless steel material, wherein the second material is an aluminum-containing material, and wherein the conduit couples the vessel to the chamber body to deposit a material layer onto a substrate seated within the chamber body using a vaporized liquid precursor communicated from with the interior of the vessel.

16. A semiconductor processing system, comprising:
a container assembly as recited in claim 1, wherein the vessel is formed from a stainless steel material, wherein the jacket is formed from an aluminum-containing material, the container assembly further comprising a thermoelectric heat pump coupled to the jacket;
a chamber arrangement coupled to the conduit and configured to deposit a material layer onto a substrate using a vaporized liquid precursor received from the container assembly; and
a controller operatively connected to the thermoelectric heat pump and responsive to instructions recorded on a memory to:
receive a temperature measurement of temperature of a liquid precursor contained within the interior of the vessel;
receive a predetermined liquid precursor temperature value;
compare the temperature measurement to a predetermined temperature value; and
throttle rate of heat transfer between the liquid precursor and an external environment using the thermoelectric heat pump when the temperature measurement received by the controller differs from the predetermined temperature measurement by more than a predetermined differential.

17. A material layer deposition method, comprising:
at container assembly including a vessel formed from a first material having a first thermal conductivity, a conduit seated in the vessel and in communication with an interior of the vessel, and a jacket extending at least in part about an exterior of the vessel and formed from a second material having a second thermal conductivity, the second thermal conductivity greater than the first thermal conductivity, the jacket affixed to the vessel with an interference fit;
receiving a carrier gas at the vessel;
vaporizing a liquid precursor contained within an interior of the vessel;
communicating the vaporized liquid precursor to a chamber arrangement coupled to the conduit using the carrier gas;
depositing a material layer onto a substrate seated within the chamber arrangement using the vaporized liquid precursor;
wherein vaporizing the liquid precursor comprises transferring heat between the liquid precursor and an external environment outside of the container assembly through the vessel and the jacket, and
wherein the interference fit between the vessel and the jacket limits resistance to heat transfer between the vessel and the jacket during transfer of the heat between the liquid precursor and the external environment.

18. A method of making a container assembly, comprising:
forming a vessel from a first material having a first thermal conductivity;
seating a conduit in the vessel such that the conduit is in communication with an interior of the vessel;
forming a jacket from a second material having a second thermal conductivity, the second thermal conductivity greater than the first thermal conductivity;
arranging the vessel in the jacket such that the jacket extends about the vessel; and
affixing the jacket to the vessel with an interference fit,
whereby the interference fit between the jacket and the vessel limits resistance to heat flow between the jacket and the vessel during transfer of the heat between a liquid precursor contained within the interior of the vessel and an external environment.

19. The method of claim 18, wherein affixing the jacket to the vessel with the interference fit comprises:
cooling the vessel prior to arranging the jacket about the vessel; and
heating the vessel subsequent to arranging the jacket about the vessel, whereby the heating of the vessel forms the interference fit between the jacket and the vessel.

20. The method of claim 18, wherein affixing the jacket to the vessel with the interference fit comprises:
heating the jacket prior to arranging the jacket about the vessel; and
cooling the jacket subsequent to arranging the jacket about the vessel, whereby the cooling of the vessel forms the interference fit between the jacket and the vessel.

21. The method of claim 18, wherein affixing the jacket to the vessel with the interference fit comprises press fitting the vessel in the jacket.
